(19) United States
(12) Patent Application Publication
(10) Pub. No.: US 2003/0176109 A1
(43) Pub. Date: Sep. 18, 2003

(54) Connecting member

(76) Inventors: Hiroaki Fukuchi, Sagamihara-shi (JP); Takashi Kuroda, Sagamihara-shi (JP); Wataru Kakinoki, Yokohama-shi (JP)

Correspondence Address: KEATING & BENNETT LLP, 10400 Eaton Place, Suite 312, Fairfax, VA, 22030, US

(21) Appl. No.: 10/377,695

(22) Filed: Mar. 4, 2003

(30) Foreign Application Priority Data
Mar. 5, 2002 (JP) 2002-058328
Mar. 25, 2002 (JP) 2002-084107

(51) Int. Cl. H01R 12/00; H05K 1/00; H01R 25/00; H01R 27/02; H01R 31/00; H01R 33/88; H01R 33/90; H01R 33/92; H01R 33/94

(52) U.S. Cl. 439/638; 439/67

(57) ABSTRACT

A connecting member includes a plurality of interface connectors for communication terminals having communication systems different from each other, the interface connectors being provided with a holder case so as not to mutually hinder the communication terminals from being connected to the respective interface connectors, and a jack connector provided in the holder case. In this connecting member, electrical wiring is arranged so as to allow the jack connector and each of the interface connectors for communication terminals to communicate with each other.

### BACKGROUND OF THE INVENTION

1. Field of the Invention

The present invention relates to a connecting member for use in interconnecting an information processing device such as a personal computer or a facsimile machine, and a mobile communication terminal such as a portable telephone or PHS (Personal Handyphone System), and in allowing communication therebetween.

2. Description of the Related Art

Previously, interfaces provided for mobile telephones such as portable telephones or PHSs have varied in the connector shape and the number of control lines depending on the communication system. A communication device, therefore, has required a connecting member having an exclusive connector for that communication device.

Here, the “connecting member” refers to a cable including a plug connector for connecting with an I/O interface PC (Personal Computer) card or a USB (Universal Serial Bus) interface device, each of which has a conversion function allowing the transmission/reception of information between an information device such as a PC and a communication terminal, and a connector for the communication terminal.

FIGS. 8A to 8D are representations of various types of conventional connecting members.

FIG. 8A is a representation of a conventional connecting member for use in interconnecting a PC card and a PHS. In FIG. 8A, an interface connector 13 for a PC card is provided on one side of a cable 11, and a 12P (pins) connector 32 for a PHS is provided on the other side thereof. The connectors 13 and 32 are integrally formed with the cable 11.

FIG. 8B is a representation of a conventional connecting member for use in interconnecting a PC card and a CDMA-One (Code Division Multiple Access One) system. In FIG. 8B, an interface connector 13 for a PC card is provided on one side of the cable 11, and an 18P (pins) connector 41 for a CDMA-One system is provided on the other side thereof. The connectors 13 and 41 are integrally formed with the cable 11.

FIG. 8C is a representation of a conventional connecting member for use in interconnecting a PC card and a PHS. In FIG. 8C, an interface connector 13 for a PC card is provided on one side of the cable 11, and a 16P (pins) connector 34 for a PHS is provided on the other side thereof. The connectors 13 and 34 are integrally formed with the cable 11.

FIG. 8D is a representation of a conventional connecting member for use in interconnecting a PC card and a PDC (Personal Digital Cellular) system. In FIG. 8D, an interface connector 13 for a PC card is provided on one side of the cable 11, and a connector 33 for a PDC is provided on the other side thereof. The connectors 13 and 33 are integrally formed with the cable 11.

As shown in FIGS. 8A to 8D, since conventional communication devices each has an exclusive connector, each connecting member is available only for a communication device having a specific communication system. Therefore, when attempting to use a communication device having another system, it has been necessary to prepare another connecting member different from the one for that specific communication system. Furthermore, when attempting to use a communication device having still another system, it has been necessary to prepare still another connecting member. With an increase in the number of types of communication devices, the types of connecting members increases, which has caused a problem in that it takes much time to manage and use such connecting members.

Also, since an exclusive connecting member is required corresponding to each individual communication system, it has been necessary to prepare an exclusive connecting member for every specific communication device. This has caused another problem in that it is difficult to secure a storage space for connecting members.

Furthermore, when attempting to use different types of communication terminals, connecting members corresponding to the respective communication terminals are required. This reduces the efficiency of work due to the poor portability of these connecting members, and increases the cost.

In the connecting members shown in FIGS. 8A to 8D, one-end sides where the same interface connectors are provided, each have a structure that can be shared among these five connecting members, but the other end sides thereof are not configured to be shared among the various types of devices. Therefore, a different connecting member must be provided for every communication device. This inability to share has reduced the usability of these connecting members.

On the other hand, as an information processing device, an interface device treated as being usable for a plurality of portable terminals such as a portable telephone and PHS, for example, an interface device equipped with a PC card and USB signal conversion circuit can be used in common among a PDC, PHS, CDMA-One and the like. However, insofar as the connecting member is concerned, a different one has been needed for every communication device, as described above.

### SUMMARY OF THE INVENTION

In order to overcome the problems described above, preferred embodiments of the present invention provide a connecting member having a configuration capable of being shared and used among various types of communication terminals.

According to a preferred embodiment of the present invention, a connecting member includes a component having a plurality of interface connectors for communication terminals having communication systems different from each other, the interface connectors being provided with a holder case that is constructed not to mutually hinder the communication terminals from being connected to the respective interface connectors. The component has also a common connection point provided with the holder case, and electrical wiring being arranged so as to allow the common connection point and each of the interface connectors for communication terminals to communicate with each other.

The connecting member according to a preferred embodiment of the present invention may have a cable, wherein one end of the cable may be brought into conduction with the common connection point, and the other end thereof may be provided with a plug connector for an information processing device.

In the connecting member, the plurality of interface connectors for communication terminals may be mounted on one printed circuit board, and on the printed circuit board, each of the connectors may be provided with electrical wiring.

In the connecting member, four types of interface connectors for communication terminals may be mounted on one printed circuit board, and a cable may be led out at an angle with respect to the plane of the printed circuit board.

The printed circuit board may have a substantially quadrangular shape, and each of the interface connectors for communication terminals may be disposed on a respective one of the sides of the printed circuit board.

A plurality of interface connectors for communication terminals may be provided with the holder case so that each of the crossing angles of the center lines of adjacent connectors is not more than approximately 90 degrees.

A plurality of interface connectors for communication terminals may be provided with the holder case so as to intersect each other substantially at right angles.

Also, the connection point may have a jack connector.

Furthermore, the plurality of interface connectors for communication terminals and the jack connector may be mounted on a printed circuit board that is provided with electrical wiring between the connectors, in a direction that is substantially parallel to the printed circuit board.

The plurality of interface connectors for communication terminals may be mounted on a printed circuit board that is provided with electrical wiring between the interface connectors and the jack connector, in the direction that is substantially parallel to the printed circuit board, and the jack connector may be positioned to the printed circuit board in the direction that is substantially perpendicular to the printed circuit board.

The connecting member may include a cable, and an interface connector for a specific communication terminal provided on one end of the cable. Herein, the jack connector may be a jack connector for receiving the interface connector for the specific communication terminal, and the holder case may include an interface connector for another communication terminal.

The connecting member also preferably includes a cable. A connector connected to one end of the cable and to be connected to a jack connector of the connecting member to which a plurality of communication terminals can be connected, and a connector connected to the other end of the cable and for use in connecting information processing device, preferably are connectors of the same specifications or standards.

The arrangements may be such that the connecting member has a cable, that an interface connector for a specific communication terminal is provided on one end of the cable, that the jack connector is a jack connector for receiving the interface connector for a specific communication terminal, and that the holder case includes an interface connector for another communication terminal. Here, a connector to be connected to the jack connector and a connector for use in connecting information processing device are preferably connectors having the same specifications.

The connector for use in connecting information processing devices may be one of a PC card interface connector and USB connector or other suitable connectors.

According to preferred embodiments of the present invention, when data communication is to be performed in communication terminals having mutually different interface specifications, the need to prepare and provide a plurality of conventional communication adapter cables is eliminated. In other words, a single connecting member enables data communication in communication terminals having a plurality of specifications.

Also, the present connecting member can be used by cable components that are usable in common between communication terminals, and components on which a plurality of connectors that are selectably usable for the communication terminals is concentratedly arranged. This reduces the number of required components, and allows the sharing of the components among the communication terminals.

Furthermore, the present connecting member makes it unnecessary to perform the management of components for each of the types of communication terminals. It suffices only to retain a single common cable component irrespective of the type of communication terminal, thereby facilitating the check and management of the cable component.

Moreover, by using the connector on one end of the cable component as a connector for a specific communication terminal, it is possible to interconnect the specific communication terminal and an information processing device by a minimum number of cable components, without the need to use a component on which a plurality of connectors is concentratedly arranged.

Besides, by using the connector on the other end (i.e., the information processing device side), of the cable component, as a PC-card interface connector or USB connector, each of which has great versatility, it is possible to connect the connecter to the information processing device with good flexibility.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a representation of a first preferred embodiment of the present invention, which shows the construction of an assembly board including three different types of interface connectors: a PDC, PHS-12P (pins), and PHS-16P (pins), on one printed circuit board;

FIG. 2 is a representation of the first preferred embodiment of the present invention, which shows an external view of the assembly board in FIG. 1 being subjected to casing;

FIGS. 3A to 3c are construction views showing a second preferred embodiment of the present invention;

FIG. 4 is an external view showing a third preferred embodiment of the present invention;

FIGS. 5A and 5B are construction views of a fourth preferred embodiment, which shows a multi-adapter and adapter cable according to the present invention;

FIGS. 6A to 6C are construction views of a fifth preferred embodiment, which shows a multi-adapter and adapter cable according to the present invention;

FIG. 7 is a construction view showing of a sixth preferred embodiment, which shows a multi-adapter and adapter cable according to the present invention; and

FIGS. 8A to 8D are representations of conventional various types of adapter cables.

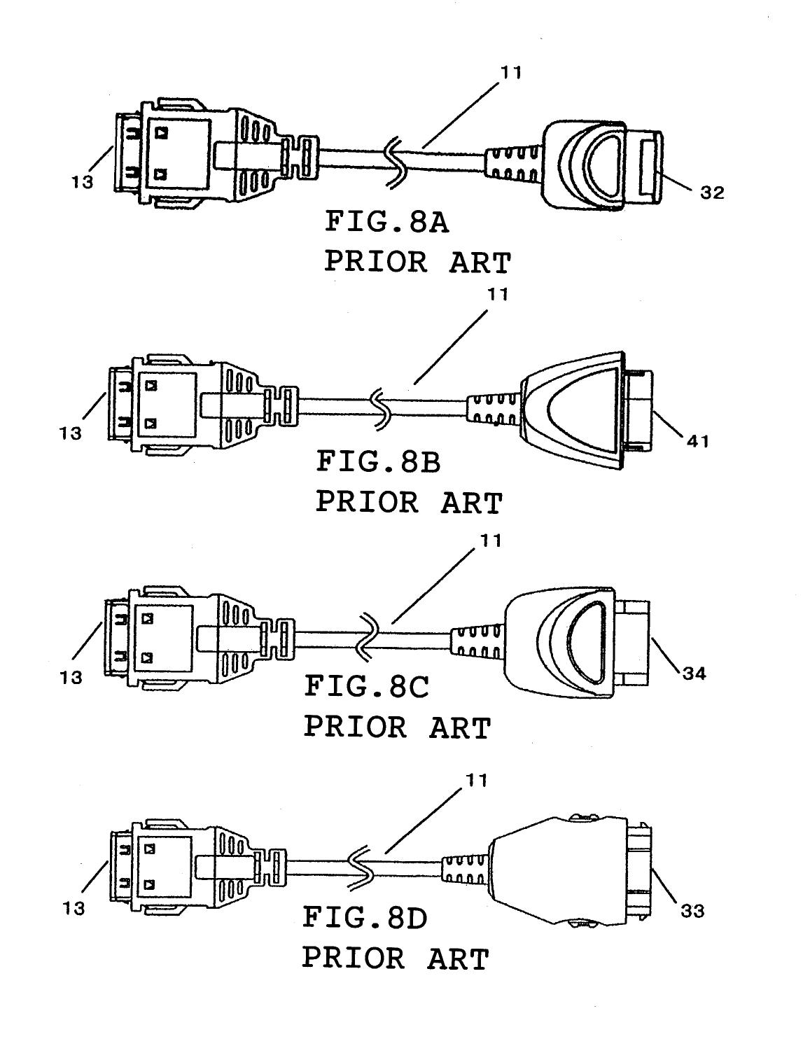

### DETAILED DESCRIPTION OF PREFERRED EMBODIMENTS

Hereinafter, preferred embodiments of a connecting member according to the present invention will be described with reference to the accompanying drawings.

The adapter cable as an example of a connecting member is for interconnecting, with a cable, the connector section for an information processing device interface, which is to be connected to an information processing device, and the connector section of a communication terminal interface, which is to be connected to a communication terminal. The connector section of an information processing device interface includes a PC-card connector to be mounted on a PC card in a PC-card slot, a USB connector, or other suitable device. The connector section of a communication terminal interface includes any number of types of interface connectors for communication terminals (hereinafter, an interface connector for a communication terminal is abbreviated as a “connector for a communication terminal”). Here, these various types of interface connectors (hereinafter, an interface connector is abbreviated as a “connector”) are accommodated in one connector holder case, and are treated as one unit.

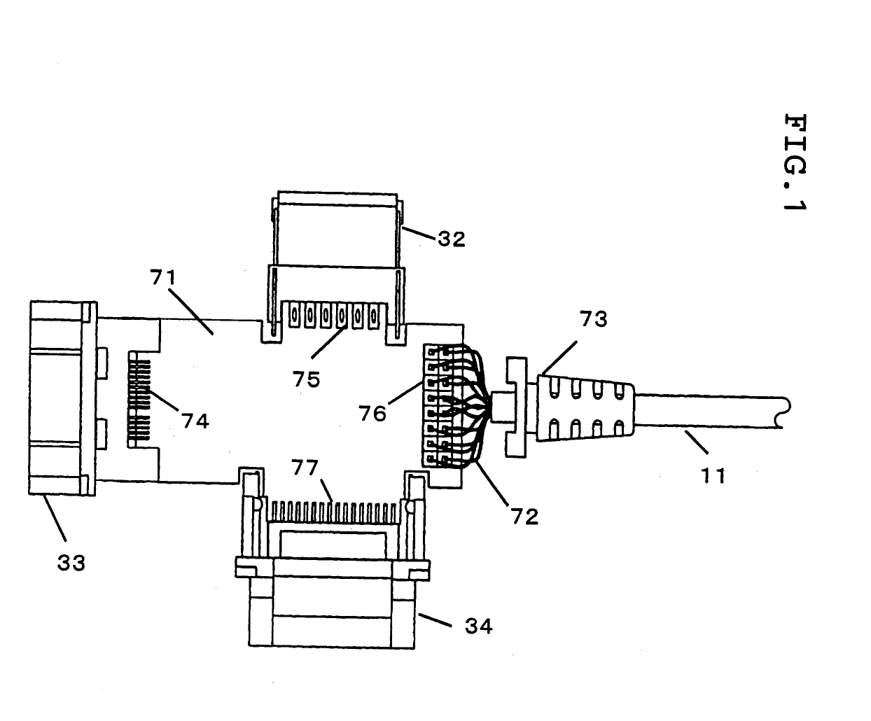

FIG. 1 is a representation of a first preferred embodiment of the present invention, which shows the construction of an assembly board including three different types of interface connectors: a PDC, PHS-12P (pins), and PHS-16P (pins), disposed on a printed circuit board.

Referring to FIG. 1, a printed circuit board 71 preferably has a substantially quadrangular shape, and the respective sides thereof have connection terminals 74 to 77. Of these terminals, at the connection terminals 74, 75, and 77 provided on three sides of the printed circuit board 71, a PDC connector 33, a PHS-12P connector 32, and a PHS-16P connector 34 are spaced apart from one another in a state in which each of the crossing angles of the center lines of adjacent connectors is approximately 90 degrees, so as not to mutually hinder the communication terminals from being connected to the respective connectors.

Wires 72 of a cable 11 to be connected to an information device (not shown) are connected to the connection terminals 76 that are provided at the one remaining side of the printed circuit board 71. Here, the cable 11 is led out in the planar direction with respect to the printed circuit board 71. The connection terminals 76 of the printed circuit board 71 and the cable 11 are connected via the wires 72. A bending margin is provided to some extent between the printed circuit board 71 and the cable 11.

On the printed circuit board 71, wiring patterns (not shown) are arranged to communicably connect all above-described connection terminals 74 to 76 according to the leading-out mode of the wires 72 of the cable 11. Each of the wiring patterns on the printed circuit board 71 is formed so as to function corresponding to a respective one of the communication devices to which respective mating connectors are to be connected.

With USB connection, as wiring patterns on the printed circuit board 71, a signal conversion circuit for converting output signals of an information processing device into signals for a communication terminal may be included, as required.

The printed circuit board 71, some portions of the connection terminals 32 to 34, and a portion of the bush 73 provided on one end side of the cable 11 are covered and fixed by the connector holder case.

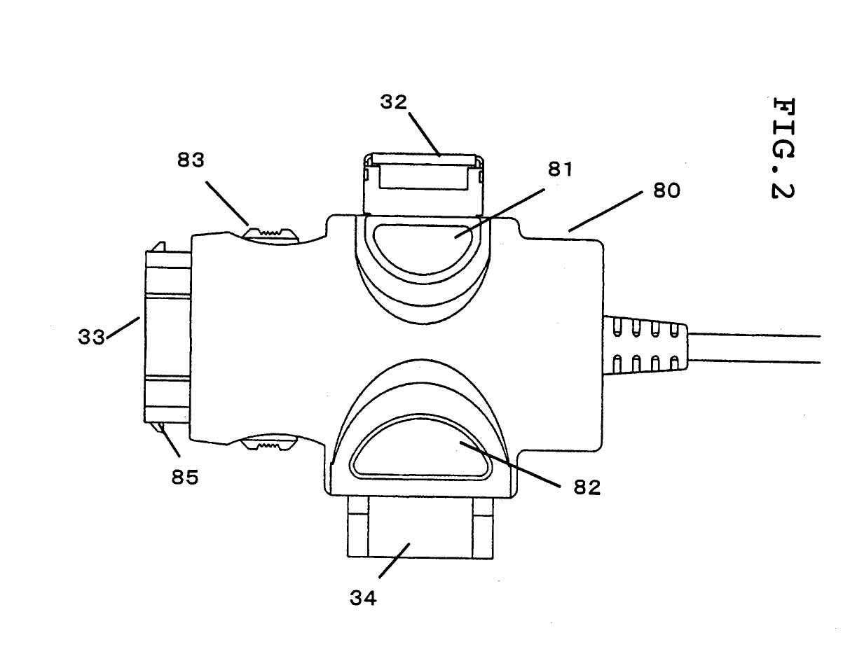

FIG. 2 is a representation of the first preferred embodiment according to the present invention, which shows an external view of the assembly board in FIG. 1 being subjected to casing.

Referring to FIG. 2, as occasion requires, a connector holder case 80 has a configuration in which halved cases are combined, or has an integrally-molded configuration. At the portion corresponding to each of the connectors, the connector holder case has an unlock button having a connector lock pawl that is engaged with the communication terminal device to be connected to the connector. The PDC connector 33 has unlock button 83 having a connector lock pawl 85. The PHS-12P connector 32 has a large-sized unlock button 81.

The PHS-16P connector 34 has also a large-sized unlock button 82. Here, with respect to the PHS-12P connector 32 and PHS-16P connector 34, the connector lock pawls therefor are not illustrated.

In this manner, since the shapes of the connectors and the unlock buttons for the communication terminals are different from one another, they are easily identifiable. Thereby, a single adapter cable enables data communication in communication terminals having three different interface specifications.

The first preferred embodiment according to the present invention eliminates the need to prepare a plurality of communication adapter cables, when attempting to perform data communication with communication terminals having mutually different interface specifications. Furthermore, this preferred embodiment makes it unnecessary to perform the management of components for each of the types of communication terminals. Thus, the first preferred embodiment of the present invention makes it sufficient to prepare only a single common adapter cable, thereby facilitating the check and management of the adapter cable.

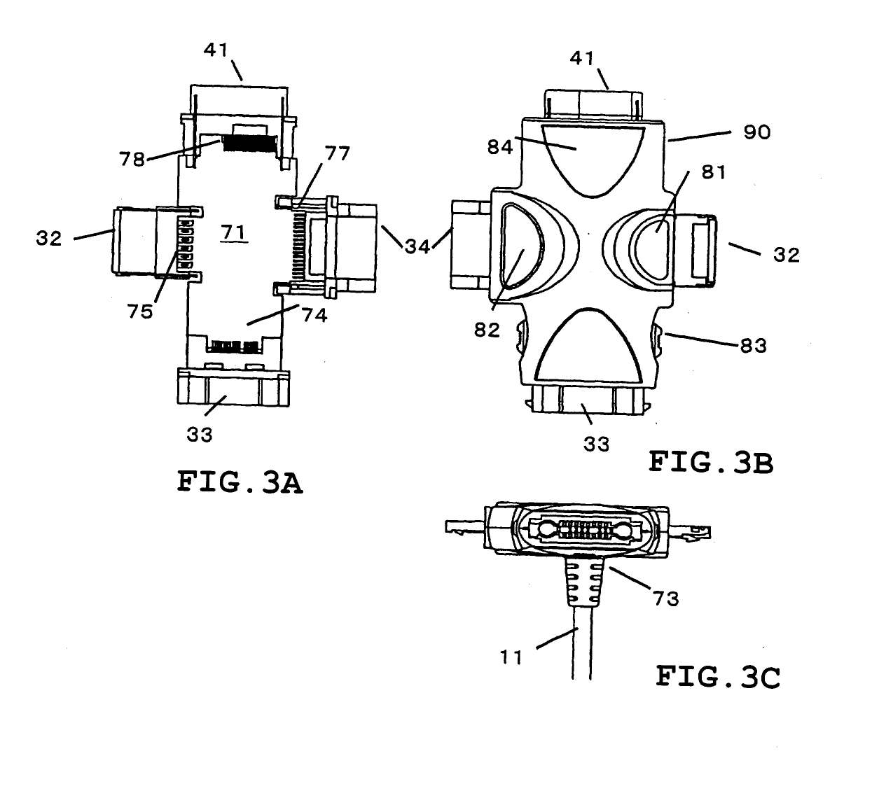

FIGS. 3A to 3c are construction views showing a second preferred embodiment according to the present invention.

FIG. 3A is a construction view showing an assembly board in which four types of connectors for communication terminals are provided on the printed circuit board.

FIG. 3B is an external view showing a state in which a holder case is provided with the assembly board.

FIG. 3C is a side view corresponding to FIG. 3B as a plan view.

This second preferred embodiment is characterized in that the leading-out of the cable in the adapter cable is performed in the direction that is substantially perpendicular to the printed circuit board.

As shown in FIG. 3A, on the plane of the printed circuit board 71, the PHS-12P connector 32, the PDC connector 33, the PHS-16P connector 34, and a CDMA-One connector 41 are spaced on the sides of the printed circuit board apart from one another by a distance such that they do not mutually hinder the communication terminals from being connected to the respective connectors, in a state in which they substantially perpendicularly intersect one another. Also, the above-described distance is set so as not to hinder undoing of respective lock buttons.

As occasion requires, one surface or both surfaces of the printed circuit board 71 are provided with wiring patterns that communicably connect all the above-described connection terminals 74, 75, 77, and 78, and the cable connection terminal (not shown, however, this corresponds to the cable connection terminal 76 in FIG. 1). Each of the wiring patterns on the printed circuit board 71 is arranged so as to function corresponding to a respective one of the communication devices to which respective mating connectors are to be connected.

Here, the four types of connectors for communication terminals are mounted on the one printed circuit board 71, and with respect to the plane of the printed circuit board 71, the cable 11 is led out at an angle other than 0 degree, preferably, at an angle of approximately 90 degrees (i.e., in the direction that is substantially perpendicular to the plane of the printed circuit board 71). This allows the connectors to be used without hindrance by the cable.

As in the case of the first preferred embodiment, as wiring patterns on the printed circuit board 71, a signal conversion circuit for converting output signals of an information processing device into signals for a communication terminal may be included, as occasion requires.

Since the printed circuit board 71 and the cable 11 are connected via wires (not shown, although these wires correspond to the wires 72 in FIG. 1), there is provided a bending margin to some extent between the printed circuit board 71 and the cable 11.

The assembly board on which the mounting of the connectors on the printer circuit board 71 shown in FIG. 3A has been completed, is covered and fixed by a connector holder case 90, together with a bush 73 for the cable 11, as shown in FIGS. 3B and 3C. Herein, substantially circular opening edges of the connector holder case 90 are fitted into concave grooves for fixing the bush 73, thereby securely fixing them. The substantially circular opening edges are provided on the opposite side of the unlock button side of the connector holder case 90.

The connector holder case 90 has a configuration in which halved cases are combined, or an integrally-molded configuration. The connector holder case 90 includes unlock buttons 81 to 84. Each of these unlock buttons has a connector lock pawl that is engaged with the connector of a mating communication terminal device. The PDC connector 33 has unlock button 83, and the PHS-12P connector 32 has an unlock button 81. Also, the PHS-16P connector 34 has an unlock button 82, and the CDMA-One connector 41 has an unlock button 84.

Since the shapes of the connectors and unlock buttons for communication terminals are different from one another, they are easily identifiable. Thereby, a single adapter cable allows data communication at a mobile unit having four different types of interface specifications.

The second preferred embodiment according to the present invention eliminates the need to prepare a plurality of communication adapter cables, when attempting to perform data communication in communication terminals having mutually different interface specifications. Furthermore, this preferred embodiment makes it unnecessary to perform the management of components for each of the types of communication terminals. This preferred embodiment makes it possible to provide only a single common adapter cable irrespective of the type of communication terminal, thereby facilitating the check and management of the adapter cable.

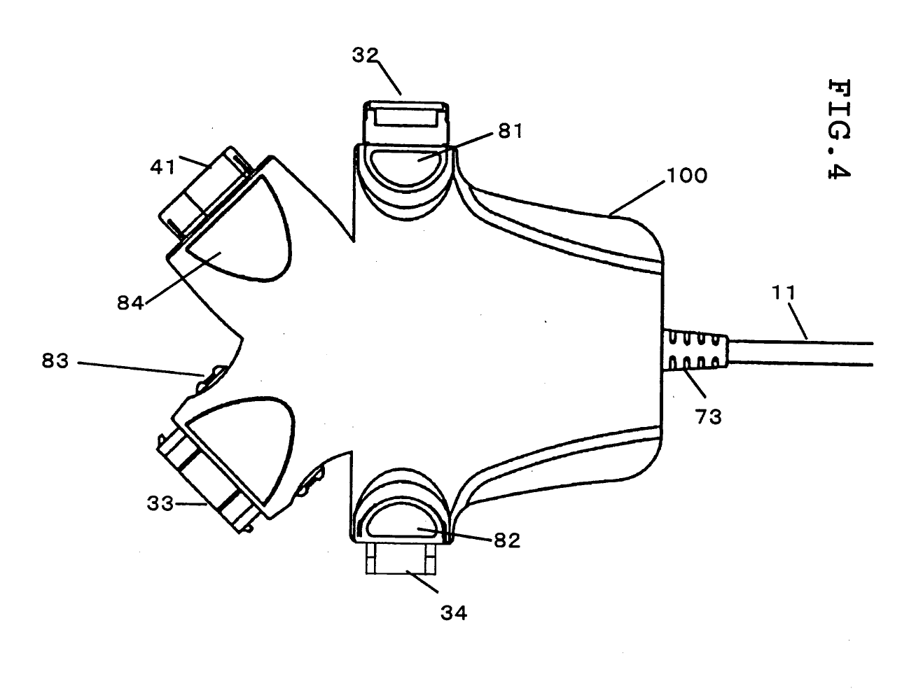

FIG. 4 is an external view showing a third preferred embodiment according to the present invention.

Referring to FIG. 4, a connector holder case 100 has a configuration in which halved cases are combined, or an integrally-molded configuration. The connector holder case 100 includes unlock buttons. Each of these unlock buttons has a connector lock pawl that is engaged with the connector of a respective one of the mating communication terminal devices. The PDC connector 33 has an unlock button 83, and the PHS-12P connector 32 has an unlock button 81. Likewise, the PHS-16P connector 34 has an unlock button 82, and the CDMA-One connector 41 has an unlock button 84.

On the plane of a printed circuit board incorporated in the connector holder case 100, the PHS-12P connector 32, PDC connector 33, PHS-16P connector 34, and CDMA-One connector 41 are spaced apart from one another by a distance such that they do not to mutually hinder the communication terminals from being connected to the respective connectors, in a state in which the center lines of adjacent connectors cross one another at arbitrary angles. Also, the above-described distance is set so as not to hinder undoing of the respective lock buttons.

One surface or both surfaces of the above-described printed circuit board are provided with wiring patterns that communicably connect all the above-described connection terminals and the connection terminal for the cable 11. Each of the wiring patterns on the printed circuit board is arranged so as to function corresponding to a respective one of the communication devices to which respective mating connectors are to be connected.

The printed circuit board has connection terminals that connect the respective connectors, and the connection terminal that connects the wires of the cable 11, and the above-described wiring patterns are connected to each of these connection terminals.

With USB connection, the wiring patterns on the printed circuit board may include a signal conversion circuit for converting output signals of an information processing device into signals for a communication terminal, as occasion requires. Since the printed circuit board and the cable 11 are connected via wires, there is provided a bending margin to some extent between the printed circuit board and the cable 11.

The third preferred embodiment shown in FIG. 4 is an example of a communication terminal connector having four connectors, as in the case of the above-described second preferred embodiment shown in FIG. 3. This example is a type in which each of the crossing angles of the center lines of adjacent connectors on the printed circuit board has been varied into any angle other than 90 degrees.

The number of connectors to be arranged is principally determined by the relationship between the area of the printed circuit board and the occupation space of connectors. Namely, the number of connectors to be arranged is confined within the range such that communication terminals connected to respective connectors do not interfere with one another when the respective connectors are fixed to the printed circuit board. As long as this condition is met, the number and types of connectors may arbitrarily be set.

The third preferred embodiment of the present invention eliminates the need to prepare a plurality of communication adapter cables, when attempting to perform data communication in communication terminals having mutually different interface specifications. Also, this preferred embodiment makes it unnecessary to perform the management of components for every type of communication terminal. This preferred embodiment makes it possible to provide only one single common adapter cable irrespective of the type of communication terminal, thereby facilitating the check and management of the adapter cable. Furthermore, in the third preferred embodiment, the range of disposition angles of all connectors with respect to the printed circuit board can be made less than that in the second preferred embodiment shown in FIG. 3, thereby allowing for significant size-reduction of the connector. Moreover, because the cable is led out in the planar direction of the printed circuit board, the overall shape can be made to be very low-profile.

Besides the above-described preferred embodiments, the following embodiments are possible.

The number of connectors to be incorporated in the holder case can be arbitrarily set if there is a sufficient margin of distance between connectors.

All interface connectors are not necessarily required to be mounted on a single board, but may be mounted on a plurality of boards according to the degree of division of the board.

Even if interface connectors are mounted on separate printed circuit boards, it would be essential only that the electrical connection therebetween be established by board-to-board connectors or the like, and that these interface connectors be accommodated in one holder case. While the present invention has been made with a view to development an interface adapter cable for connecting a PC card and a communication terminal, the present invention would produce similar effects in the cases of various I/O cards including a CF (Compact Flash®) card, as well. Furthermore, also in the case where a USB port provided for a personal computer or other device is to be connected to a communication terminal, an adapter cable could be implemented with a similar configuration. Each of the connectors and the cable wires may be directly connected without the interposition of the board.

Each of the connectors is provided with a cap for keeping out foreign matter as occasion requires, and has the cap mounted thereon while the connector is not used. Each of the caps is connected to the holder case 100 by a connecting element made of, for example, a resin having flexibility.

The cap is changed in the display and color for every communication terminal. This facilitates identifying communication terminals.

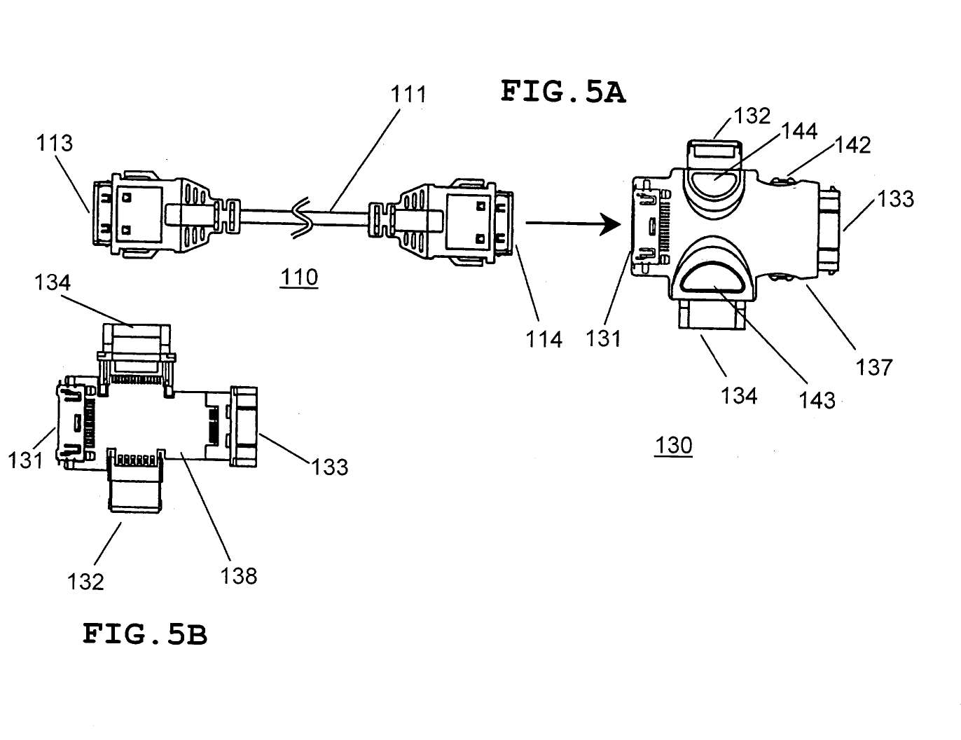

FIGS. 5A and 5B are construction views of a fourth preferred embodiment, which shows a multi-adapter, adapter cable according to the present invention, and the internal structure of this multi-adapter.

An example shown in FIG. 5A is a combination of a multi-adapter 130 including three different types of connectors 132 to 134 for communication terminals and an adapter cable 110.

Of these, the adapter cable 110 includes a cable 111, an interface connector 113 for a PC card, which is provided on one end of the cable 111, as a cable adapter, and a cable connector 114, which is provided on the other end side of the cable 111, as a cable adapter.

The interface connector 113 for a PC card has a connector shape so as to be connected to a data communication adapter card for PHS, PDC or other device, in a state in which such a card has been inserted into the card slot of a personal computer. Because the interface connector 113 for a PC card and the cable connector 114 are male connectors, they each have an unlock button.

The multi-adapter 130 has an internal structure shown in FIG. 5B and an external structure shown in FIG. 5A. In the internal structure, on three sides of substantially the same plane as that of a printed circuit board 138, there are provided communication interface connectors 132, 133, and 134 (i.e., PHS-12P, PDC, and PHS-16P, respectively) having three different types of interfaces. On the remaining one side of substantially the same plane as that of the printed circuit board 138, there is provided a jack connector 131. The jack connector 131 is configured to be connected to the cable connector 114 of the adapter cable 110.

The connecting pins of the jack connector 131 are connected, in common, to those of the PHS-12P connector 132, those of the PHS-16P connector 134, and those of the PDC connector 133, by the wiring structure of the printed circuit board 138.

The wiring pattern on the printed circuit board 138 is arranged so as to function for each of the communication terminals to which the respective one of the connectors is connected.

While these interface connectors for communication terminals preferably have a projected shape on three sides of substantially the same plane as that of the printed circuit board 138, another interface connector for a communication terminal may also be disposed on a plane that is substantially perpendicular to this plane so as to be projected from the printed circuit board.

The interface connectors assume a spatial structure in which, when communication terminals are to be installed thereto, the interface connectors for communication terminals are spaced apart from one another by a distance so as not to interfere with one another, and in which, when one of the connectors is in a connected state, the others do not interfere with the connection of that one connecter and neither hinders undoing of the lock button of the one connector.

The number of types of the communication terminals that can be provided with the multi-adapter 130 is basically planned so that each type of the communication terminals can be installed to a respective one of the connectors, and up to three types of the communication terminals are simultaneously installable in all.

In the multi-adapter according to this preferred embodiment, although the number of interface connectors for communication terminals is preferably three, the number thereof can be structurally set to any number that is four or less.

As another example of the printed circuit board 138, there is one that can mount thereon a signal conversion circuit for converting output signals of the personal computer into communication signals for each of the communication terminals. The use of this type of printed circuit board eliminates the need for a PC card, and allows the printed circuit board to be directly connected to the personal computer by USB connection.

The external structure of the multi-adapter 130 includes the printed circuit board 138 shown in FIG. 5B and a holder case 137 for fixing the connectors 131 to 134. Each of the connectors in the holder case 137 has an unlock button. Specifically, the jack connector 131 is female connector, and the PHS-12P connector 132, PDC connector 133, and PHS-16P connector 134 have unlock buttons 144, 142, and 143, respectively.

In this case, the electrical connection among the connectors is implemented by the printed circuit board, but the electrical connection therebetween may be established by directly connecting the connectors using cables.

The interface connector 113 for a PC card is installed to a data communication adapter card of PHS, PDC, or other device that has been inserted into the card slot of the personal computer, and then the cable connector 114 provided at the other end of the cable 111 is installed to the jack connector 131 of the multi-adapter 130.

In this state, the male PHS-12P connector 132, for example, is installed to a female PHS-12P connector of a PHS (not shown). This puts the PHS into operation.

Previously, when data communication is to be performed in communication terminals having mutually different interface specifications, it has been necessary to prepare adapter cables for respective communication terminals (in this example, three adapter cables for 12-pin PHS, 16-pin PHS, and PDC). In the fourth preferred embodiment of the present invention, however, it suffices to prepare the adapter cable 110, which is usable in common among communication terminals, and the multi-adapter 130, which can be selectably used for communication terminals. This reduces the number of required components, and enables the components to be shared among the communication terminals.

Because the electrical wiring is performed on the printed circuit board, the need to separately perform complicated wiring is avoided. This improves the reliability, and produces the effect of reducing malfunction occurring in assembly. Also, because the opposite ends of the cable use the same cable connectors, the commonality of components can be achieved. Furthermore, because the multi-adapter and adapter cable define a separable structure, they do not put much load on the cable when they are carried, thereby increasing the endurance of the cable.

Thus, a single multi-adapter allows data communication in communication terminals having a plurality of specifications.

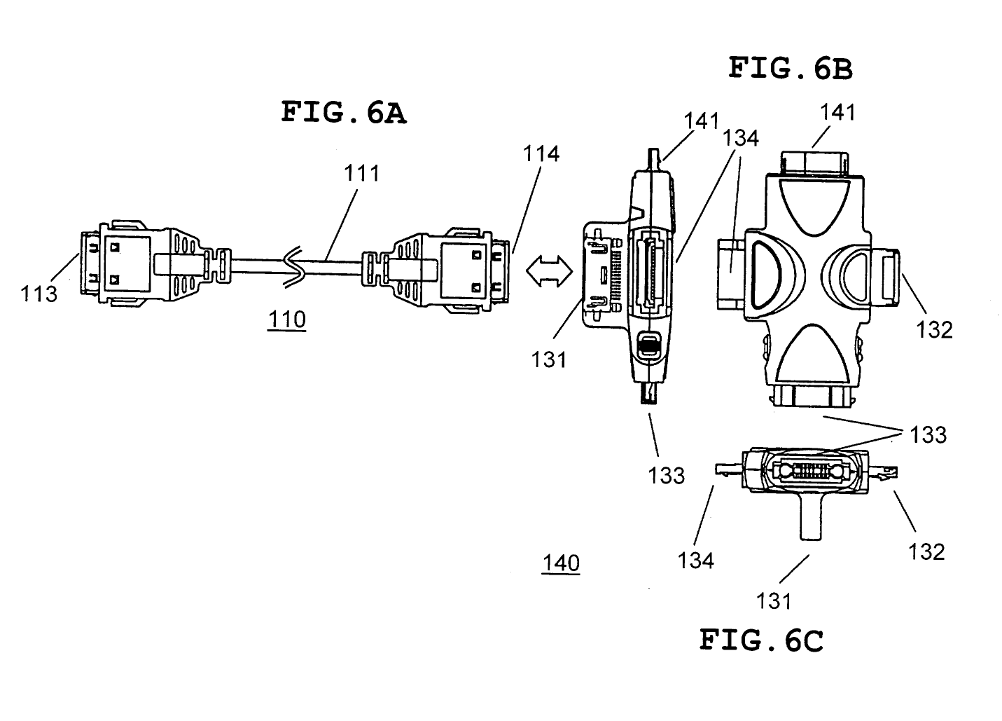

FIGS. 6A to 6C are construction views of a fifth preferred embodiment showing an adapter cable 110 with common specifications, and a multi-adapter 140 including plural types of communication interface connectors and a jack connector.

FIG. 6A is a construction view showing a common-specification adapter cable 110 defined by connecting the interface connector 113 for a PC card and the cable connector 114 by the cable 111, and a multi-adapter 140 including communication interface connectors 132, 133, 134, and 141 (i.e., PHS-12P, PDC, PHS-16P, and CDMA-One, respectively) having four different types of interfaces, the interface connectors being mounted on the four sides of substantially the same plane as that of the printed circuit board, and the jack connector 131 disposed in the direction that is substantially perpendicular to the plane on which the adapters are mounted.

FIG. 6B is a plan view of the multi-adapter 140 in FIG. 6A, when seen from the right side.

FIG. 6C is a side view of the multi-adapter 140 corresponding to FIG. 6B, which is a representation thereof when seen from the downside of the multi-adapter 140 in FIG. 6B along the plane of the drawing.

The jack connector 131 is disposed in the direction that is substantially perpendicular to the plane on which the four connectors are mounted, and each of the terminals of the jack connector 131 and the respective one of the terminals of the four types of interface connectors for communication terminals are connected in the inside via the wiring patterns of the printed circuit board.

The connection between the jack connector 131 and the printed circuit board may be established via a board-to-board connector, or alternatively, may be performed by directly soldering leads. Still alternatively, the jack connector 131 and the printed circuit board may connected via a cable.

The interface connectors for communication terminals preferably have a projected shape on the four sides of substantially the same plane. Furthermore, another interface connector for a communication terminal could be disposed on a plane other than the plane on which the jack connector 131 is mounted, and which is substantially perpendicular to the aforementioned plane.

The number of types of the communication terminals that can be provided with the multi-adapter 130 is basically planned so that each type of the communication terminals can be installed to a respective one of the connectors, and therefore, up to four types of the communication terminals are simultaneously installable in all.

In this case, no concurrent use of these communication terminals is conducted, but it is necessary to select, on the personal computer side, the type of communication terminals at which communication is performed. Also, a device for preventing mutual interference is required.

As another example of this printed circuit board, there is one that can mount thereon a signal conversion circuit for converting output signals of the personal computer into communication signals for each of the communication terminals. Use of this type of printed circuit board would allow the printed circuit board to be directly connected to the personal computer by USB connection.

The interface connectors assume a spatial structure in which the interface connectors for communication terminals are spaced apart from one another by a distance so as not to interfere with one another when communication terminals are to be installed, and in which, when one connector is in a connected state, other connectors do not interfere with the connection of the one connecter and neither hinders undoing of the lock button of the one connector.

The number of interface connectors for communication terminals can be arbitrarily set within the range in which sufficient mutual distances therebetween can be provided.

With regard to matters other than those described above, the present preferred embodiment has arrangements similar to those of the above-described fourth preferred embodiment.

Thus, a single adapter allows data communication in mobile communication terminals having four different interface specifications.

The fifth preferred embodiment according to the present invention eliminates the need to prepare a plurality of communication adapter cables, when attempting to perform data communication in communication terminals having mutually different interface specifications. Also, because the electrical wiring is performed on the printed circuit board, the need to separately perform complicated wiring is avoided. This improves the reliability, and produces the effect of reducing malfunction occurring in assembly. Furthermore, because the opposite ends of the cable use the same cable connectors, the commonality of components can be achieved. Moreover, because the multi-adapter and adapter cable define a separable structure, they do not put much load on the cable when being carried, thereby increasing the endurance of the cable.

Thus, a single multi-adapter adapter enables data communication in a maximum of four communication terminals having mutually different interface specifications. Other effects are the same as those achieved by the above-described first preferred embodiment.

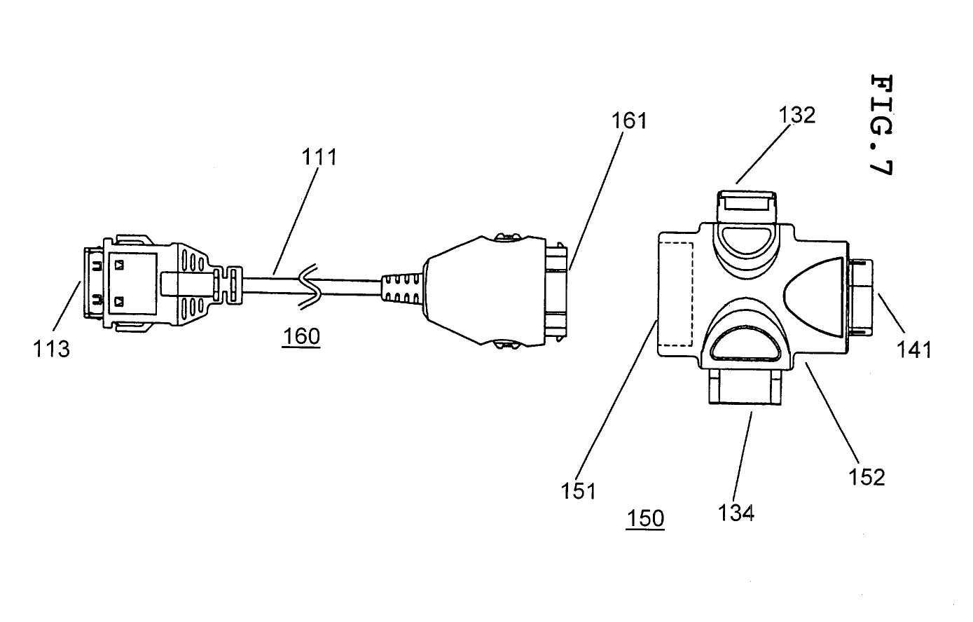

FIG. 7 is a construction view showing a sixth preferred embodiment of a multi-adapter and adapter cable according to the present invention.

FIG. 7 shows an adapter cable 160 formed by connecting the interface connector 113 for a PC card and a PDC male connector 161 by the cable 111, and multi-adapter 150 including three interface connectors for communication terminals: PHS-12P connector 132, CDMA-One connector 141, and PHS-16P connector 134, and a PDC female connector 151 used as a jack connector.

The adapter cable 160 has a male connector 161 disposed at one end thereof, and therefore, can be independently used as a PDC adapter cable without the need to use the multi-adapter 150.

The terminal of the PDC female connector 151 and the terminal of each of the PHS-12P connector 132, CDMA-One connector 141, and PHS-16P connector 134 are operably connected to one another by the wiring patterns of the printed circuit board.

When the adapter cable 160 alone is used, a PDC can be connected via the PDC male connector 161. Also, by connecting the PDC female connector 151 of the adapter 150 to the PDC male connector 161, PHS and CDMA-One can be connected to corresponding PHS-12P connector 132, PHS-16P connector 134, and CDMA-One connector 141.

As a connector to be used at one end of the adapter cable 160, any of the PHS-12P connector 132, CDMA-One connector 141, and PHS-16P connector 134 may be selected. When the selection has been done, the jack connector is used as a female connector for the selected type, and the interface connector for a communication terminal provided with the multi-adapter 150 is used as an interface connector for a type other than the selected type.

With regard to matters other than those described above, the present preferred embodiment has arrangements similar to those of the above-described fourth preferred embodiment.

In the sixth preferred embodiment according to the present invention, the cable in itself can be used as an adapter cable, and therefore, when the multi-adapter is to be used, the number of usable types of communication terminals is increased by one than that in the above-described fourth and fifth embodiments. The number of components is small as compared with that in the multi-adapter having four interface connectors for communication terminals, thereby achieving cost reduction. Other effects is the same as those achieved by the above-described fourth preferred embodiment.

The seventh preferred embodiment according to the present invention will be described below.

Interface connectors for communication terminals are provided on a plurality of different printed circuit boards, and after being electrically connected by a board-to-board connector or the like, these different printed circuit boards are accommodated in a holder case.

The seventh preferred embodiment according to the present invention enables a plurality of interface connectors for communication terminals to be arranged in any direction, without being restricted to one specific printed circuit board.

As other preferred embodiments not disclosed in the above-described preferred embodiments, there are at least two (1) and (2), which are described as follows.

(1) As an interface connector for a communication terminal for the above-described adapter, or as a cable connector for the adapter cable, an interface connector based on the third generation mobile telephone system IMT-2000 (W-CDMA) can be used.

Here, “IMT-2000” refers to “International Mobile Telecommunications 2000”, and “W-CDMA” refers to “Wideband Code Division Multiple Access”.

The major features of the aforementioned connector are as follows. This connector is an SMT (Surface Mount Technology)-adaptable 10P interface connector with a coaxial terminal or cable, having a shape conforming to the EIAJ (Electronic Industries Association of Japan) standards, and complies with the USB standards. Also, this connector constitutes a composite connector having 10 signal poles and 1 RF (Radio Frequency) pole.

(2) In the above-described adapter cable, a USB interface plug connector can be used instead of a PC-card interface connector. The personal computer corresponding to the USB standards is a PC/AT (Personal Computer/Advanced Technology) compatible personal computer equipped with a Windows® 98SE/ME/2000 or the like, which is equipped with the USB as standard.

The above-described other preferred embodiment (1) enables high-speed communication and hot insertion and removal of the PC card, and improves operability.

The above-described other preferred embodiment (2) eliminates the need for a typically necessary PC card, thereby allowing data communication to be implemented without the need to use a PC-card slot. Also, even when the personal computer body is live, the plug connecter can be freely inserted and withdrawn. Furthermore, because a control system (AT command), which is frequently used in general modems) is adopted, no specific setting is necessary.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A connecting member having a component, the connecting member comprising:
a holder case;
a plurality of interface connectors for communication terminals having communication systems different from each other, said plurality of interface connectors being provided within said holder case so as not to mutually hinder the communication terminals from being connected to the respective interface connectors;
a common connection point provided within said holder case; and
electrical wiring being arranged so as to allow said common connection point and each of said interface connectors for communication terminals to communicate with each other.

2. The connecting member according to claim 1, further comprising a cable, wherein a first end of said cable is in conduction with said common connection point, and a second end of said cable is provided with a plug connector for an information processing device.

3. The connecting member according to claim 1, further comprising a printed circuit board, wherein said plurality of interface connectors for communication terminals is mounted on said printed circuit board, and wherein, on said printed circuit board, each of said plurality of interface connectors is provided with electrical wiring.

4. The connecting member according to claim 1, further comprising a printed circuit board, wherein four types of interface connectors for communication terminals are mounted on said printed circuit board, and wherein a cable is arranged and led out at an angle with respect to the plane of said printed circuit board.

5. The connecting member according to claim 3, wherein said printed circuit board has a substantially quadrangular configuration, and wherein each of said interface connectors for communication terminals are disposed on a respective one of the sides of said printed circuit board.

6. The connecting member according to claim 4, wherein said printed circuit board has a substantially quadrangular configuration, and wherein each of said interface connectors for communication terminals are disposed on a respective one of the sides of said printed circuit board.

7. The connecting member according to claim 1, wherein said plurality of interface connectors is provided within said holder case so that each of the crossing angles of the center lines of adjacent ones of said plurality of interface connectors is not more than approximately 90 degrees.

8. The connecting member according to claim 1, wherein said plurality of interface connectors terminals is arranged so as to intersect each other substantially at right angles with respect to each other.

9. The connecting member according to claim 1, wherein said connection point includes a jack connector.

10. The connecting member according to claim 9, further comprising a printed circuit board that is provided with electrical wiring between said plurality of interface connectors connectors in a direction that is substantially parallel to said printed circuit board, wherein said plurality of interface connectors and said jack connector are mounted on said printed circuit board.

11. The connecting member according to claim 9, further comprising a printed circuit board, wherein said plurality of interface connectors are mounted on said printed circuit board that is provided with electrical wiring between said interface connectors and said jack connector in a direction that is substantially parallel to said printed circuit board, and wherein said jack connector is positioned on said printed circuit board in a direction that is substantially perpendicular to said printed circuit board.

12. The connecting member according to claim 9, further comprising a cable, and an interface connector for a specific communication terminal provided on one end of said cable, wherein said jack connector receives said interface connector for the specific communication terminal, and wherein said holder case includes an interface connector for another communication terminal.

13. The connecting member according to claim 1, wherein the holder case includes two separate half-case members that are joined together to define the holder case.

14. The connecting member according to claim 1, wherein the connector holder case has an unlock button having a connector lock pawl that is engaged with a communication terminal to be connected to one of said plurality of interface connectors.

15. The connecting member according to claim 9, wherein said jack connector includes connecting pins which are connected in common to said plurality of interface connectors.

16. The connecting member according to claim 1, wherein said plurality of interface connectors include a PHS-12P connector, a PDC connector, a PHS-16P connector, and a CDMA-One connector.

17. The connecting member according to claim 1, wherein each of said plurality of interface connectors in the holder case has an unlock button.

18. The connecting member according to claim 1, wherein the number of said plurality of interface connectors is between 2 and 4.

19. A connecting member comprising a cable, a first connector, a second connector, and a jack connector, said first connector being connected to a first end of said cable and to be connected to said jack connector of said connecting member to which a plurality of communication terminals can be connected, and a second connector connected to a second end of said cable and for use in connecting an information processing device, wherein said first and second connectors have the same specifications.

20. The connecting member according to claim 19, wherein said connector for use in connecting an information processing device is one of a PC card interface connector and a USB connector.
